(19) United States
(12) Patent Application Publication
(10) Pub. No.: US 2014/0134418 A1
(43) Pub. Date: May 15, 2014

(54) FORMING A PIEZOELECTRIC MEMBRANE

(71) Applicant: NATIONAL TAIWAN UNIVERSITY, Taipei (TW)

(72) Inventors: Chih-Kung Lee, Taipei City (TW); Han-Lung Chen, New Taipei City (TW); Hsu-Ching Liao, Taichung City (TW)

(73) Assignee: NATIONAL TAIWAN UNIVERSITY, Taipei (TW)

(21) Appl. No.: 13/736,090

(22) Filed: Jan. 8, 2013

(30) Foreign Application Priority Data
Nov. 14, 2012 (TW) 101142415

(51) Int. Cl. H01L 41/317; H01L 41/193

(52) U.S. Cl. CPC H01L 41/317; H01L 41/193
USPC 428/220; 442/110; 442/115; 428/221; 427/100

(57) ABSTRACT

A piezoelectric membrane and a forming method thereof are provided, wherein the method of forming the piezoelectric membrane includes providing a porous substrate film, which is a membrane structure formed by a plurality of fibers and has two main surfaces. Then, piezoelectric material solution is permeated into the porous substrate film and then hardened, such that the fibers are partially covered with the piezoelectric material.

### CROSS-REFERENCE TO RELATED APPLICATION

This application claims the priority benefit of Taiwan application serial no. 101142415, filed on Nov. 14, 2012. The entirety of the above-mentioned patent application is hereby incorporated by reference herein and made a part of this specification.

### BACKGROUND OF THE INVENTION

1. Field of the Invention

The invention relates to a piezoelectric membrane and a forming method thereof, and more particularly to a porous piezoelectric membrane and a forming method thereof.

2. Description of Related Art

In comparison with piezoelectric ceramic materials, a piezoelectric polymer material has a number of advantages such as being easy to be processed, being capable of forming extra thin film with a large area, having flexibility and impact-resistance, its sound impedance being similar to that of water and a living body, and so on. Therefore, the piezoelectric polymer material is widely applied to thin-film pressure sensors and ultrasonic transducers.

Since the piezoelectric polymer material is solid in structure, there is an acoustic impedance mismatch between the piezoelectric polymer material and air, which restricts its applications to the pressure sensors and ultrasonic transducers in air media. Consequently, the idea of making porous piezoelectric polymer film is surfaced so as to further match air impedance in recent years.

However, the conventional chemical methods of forming the porous piezoelectric polymer film such as phase transformation, phase separation, adding emulsifiers, and etc. result in the porous piezoelectric polymer film with lower piezoelectric effect due to the influence of the solution polarity; moreover, it is not able to form large-areaed and high-porous piezoelectric membrane by these methods. Therefore, a method of forming the large-areaed and porous piezoelectric membrane effectively is required.

### SUMMARY OF THE INVENTION

The invention provides a method of forming a piezoelectric membrane, through which a large-areaed porous piezoelectric membrane may be formed.

The invention further provides a method of forming a piezoelectric membrane, through which a porous piezoelectric membrane with a porosity of 10% to 95% may be formed.

The invention provides a porous piezoelectric membrane.

The invention further provides a porous piezoelectric membrane with a porosity of up to 10% or more.

The invention provides a method of forming a piezoelectric membrane, which includes steps of permeating piezoelectric material solution into the porous substrate film and then hardening the piezoelectric material solution, and thus forming a porous piezoelectric membrane fast and easily.

The invention also provides a piezoelectric membrane, which is a composite piezoelectric membrane combining piezoelectric material and porous substrate film made of porous electret material.

The invention provides a method of forming a piezoelectric membrane. First, a porous substrate film is provided. The porous substrate film is a membrane structure having a plurality of fibers and having two main surfaces. Then, a piezoelectric material solution is permeated into the porous substrate film and then hardened, such that the fibers are partially covered with the piezoelectric material.

According to one embodiment of the invention, in the method of forming the piezoelectric membrane, a method of permeating the piezoelectric material solution into the porous substrate film includes coating the piezoelectric material solution on the porous substrate film.

According to one embodiment of the invention, in the method of forming the piezoelectric membrane, a method of coating the piezoelectric material solution on the porous substrate film may include spin coating, blade coating, or screen printing.

According to one embodiment of the invention, in the method of forming the piezoelectric membrane, a method of permeating the piezoelectric material solution into the porous substrate film includes immersing the porous substrate film in the piezoelectric material solution.

According to one embodiment of the invention, in the method of forming the piezoelectric membrane, the piezoelectric material solution is formed by dissolving the piezoelectric material in a solvent. The piezoelectric material includes polyhexamethylene adipamide, poly(vinylidene fluoride) (PVDF), poly(vinylidenefluoride-trifluoroethylene) (P(VDF-TrFE)), polymide, or poly(L-lactic acid) (PLLA). The solvent includes acetone or tetrahydrofuran. The concentration of the piezoelectric material in the piezoelectric material solution is 20 percent by weight or less.

According to one embodiment of the invention, the method of forming the piezoelectric membrane further includes wetting the porous substrate film by an enhancer solution before coating the piezoelectric material solution on the porous substrate film, wherein a polarity of the enhancer solution is lower than that of the solvent for the piezoelectric material solution.

According to one embodiment of the invention, in the method of forming the piezoelectric membrane, the piezoelectric material solution is formed by dissolving the piezoelectric material in a solvent. The piezoelectric material includes polyhexamethylene adipamide, poly(vinylidene fluoride) (PVDF), poly(vinylidenefluoride-trifluoroethylene) (P(VDF-TrFE)), polymide, or poly(L-lactic acid) (PLLA). The solvent includes dimethyl formamide, dimethyl acetamide, or dimethyl sulfoxide, and the enhancer solution includes acetone or tetrahydrofuran. The concentration of the piezoelectric material in the piezoelectric material solution is 20 percent by weight or less.

According to one embodiment of the invention, in the method of forming the piezoelectric membrane, a material of the porous substrate film includes porous electret material.

According to one embodiment of the invention, in the method of forming the piezoelectric membrane, a material of the porous substrate film includes polypropylene (PP), polytetrafluoroethylene (PTFE), expanded polytetrafluoroethylene (e-PTFE), polycarbonate (PC), polymethylmethacrylate (PMMA), or polyethylene terephthalate (PET).

According to one embodiment of the invention, the method of forming the piezoelectric membrane further includes coating a polymer solution on the two main surfaces of the porous substrate film and then hardening the polymer solution after the piezoelectric material solution is hardened.

According to one embodiment of the invention, the method of forming the piezoelectric membrane further includes polarizing the piezoelectric membrane before coating the polymer solution on the two main surfaces of the porous substrate film and then hardening the polymer solution.

According to one embodiment of the invention, the method of forming the piezoelectric membrane further includes polarizing the piezoelectric membrane after coating the polymer solution on the two main surfaces of the porous substrate film and then hardening the polymer solution.

According to one embodiment of the invention, in the method of forming the piezoelectric membrane, the polymer solution is formed by dissolving a polymer material in a solvent. The polymer material includes polypropylene, polystyrene (PS), polycarbonate, polyvinyl chloride (PVC), polymethylmethacrylate (PMMA), polyethylene terephthalate (PET), poly-tetrafluoroethylene (PTFE), fluorinated ethylene propylene (FEP), or cyclic olefin copolymer (COC).

The invention provides another piezoelectric membrane which includes a porous substrate film and a piezoelectric material, wherein the porous substrate film is a membrane structure having two main surfaces and is formed by a plurality of fibers, and the plurality of fibers are partially covered with the piezoelectric material.

According to another embodiment of the invention, in the piezoelectric membrane, a material of the porous substrate film includes a porous electret material.

According to another embodiment of the invention, in the piezoelectric membrane, the porous electret material includes polypropylene (PP), polytetrafluoroethylene (PTFE), expanded polytetrafluoroethylene (e-PTFE), polycarbonate (PC), polymethylmethacrylate (PMMA), or polyethylene terephthalate (PET).

According to another embodiment of the invention, in the piezoelectric membrane, the piezoelectric material includes polyhexamethylene adipamide, poly(vinylidene fluoride) (PVDF), poly(vinylidenefluoride-trifluoroethylene) (P(VDF-TrFE)), polymide, or poly(L-lactic acid) (PLLA).

According to another embodiment of the invention, a porosity of the piezoelectric membrane is 10% to 95%.

According to another embodiment of the invention, a porosity of the piezoelectric membrane is 60% to 80%.

According to another embodiment of the invention, the piezoelectric membrane further includes a polymer layer disposed on the two main surfaces of the porous substrate film.

According to another embodiment of the invention, in the piezoelectric membrane, a material of the polymer layer includes polypropylene, polystyrene (PS), polycarbonate, polyvinyl chloride (PVC), polymethylmethacrylate (PMMA), polyethylene terephthalate (PET), poly-tetrafluoroethylene (PTFE), fluorinated ethylene propylene (FEP), or cyclic olefin copolymer (COC).

According to another embodiment of the invention, a thickness of the piezoelectric membrane is 1 μm to 1 mm.

Accordingly, the method of forming the piezoelectric membrane provided in the invention includes steps of permeating the piezoelectric material solution into the porous substrate film and then hardening the piezoelectric material solution, so that a porous piezoelectric membrane is formed. In addition, the piezoelectric membrane provided in the invention may be a composite piezoelectric membrane having the porous substrate film made by the porous electret material and the piezoelectric material.

In order to make the aforementioned features and advantages of the invention more comprehensible, embodiments accompanying figures are described in detail below.

### BRIEF DESCRIPTION OF THE DRAWINGS

FIG. 1 is a flow chart of forming a piezoelectric membrane according to an embodiment of the invention.

FIG. 2 is a schematic cross-sectional view of a piezoelectric membrane according to an embodiment of the invention.

FIG. 3 is a schematic cross-sectional view of a piezoelectric membrane according to another embodiment of the invention.

### DESCRIPTION OF EMBODIMENTS

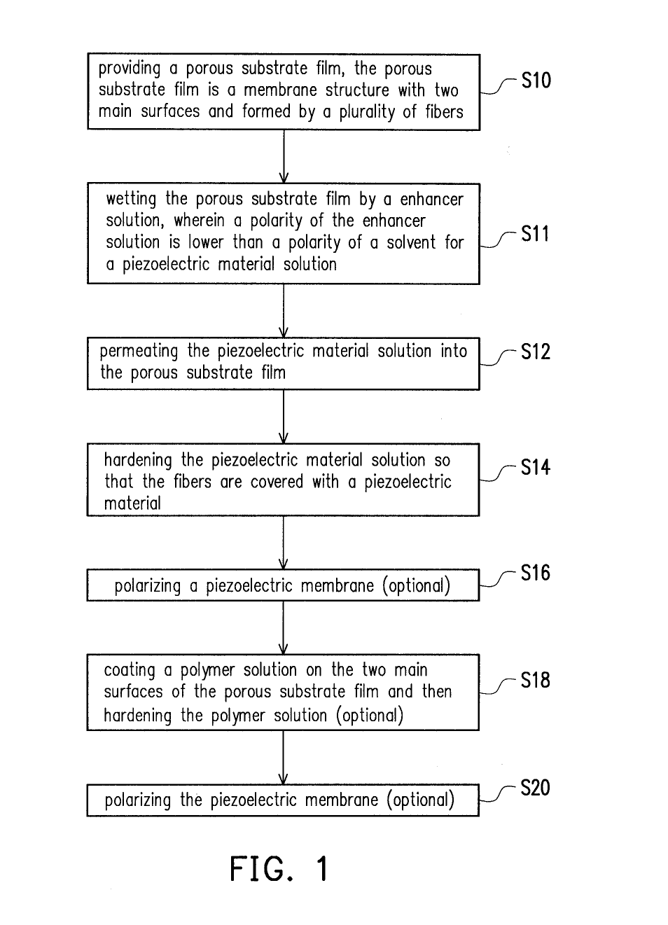

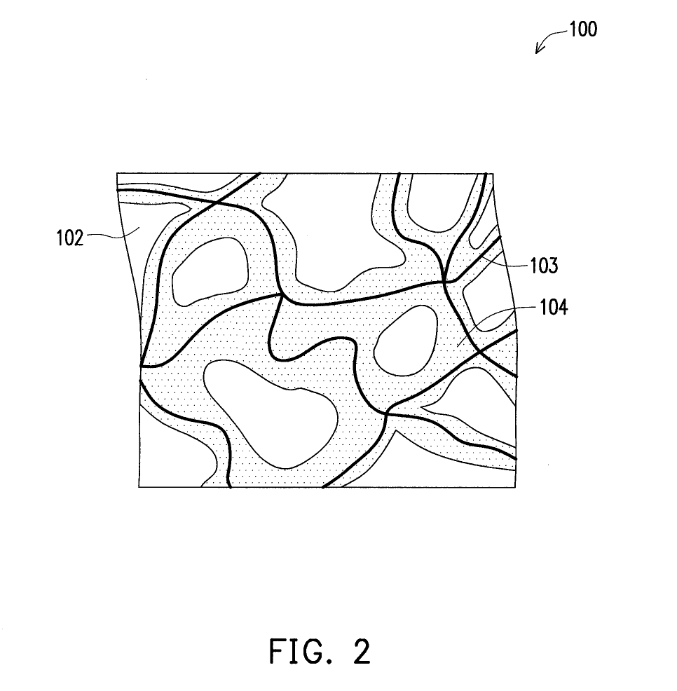

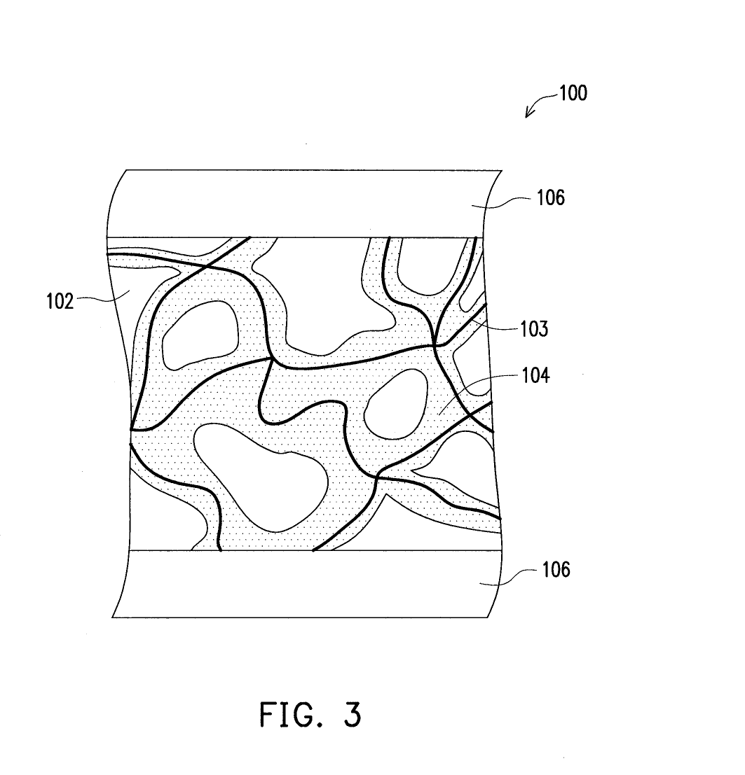

FIG. 1 is a flow chart of forming a piezoelectric membrane according to an embodiment of the invention. FIG. 2 is a schematic cross-sectional view of a piezoelectric membrane according to an embodiment of the invention. FIG. 3 is a schematic cross-sectional view of a piezoelectric membrane according to another embodiment of the invention. In order for the characteristics of the invention to be clearly presented, layers and structure in FIG. 2 and FIG. 3 are not illustrated necessarily based on an actual proportion.

Please refer to both FIGS. 1 and 2. A step S10 is carried out. A porous substrate film 102 is provided, which is a membrane structure formed by a plurality of fibers 103 and has two main surfaces. The material of the porous substrate film 102 is, for example, porous electret material which usually has a hydrophobic characteristic as well as a quasi-permanent electric charge, and also has a piezoelectric characteristic due to space dipoles stored in pores therein. In the embodiment, the porous electret material is, for example, polypropylene (PP), polytetrafluoroethylene (PTFE), expanded polytetrafluoroethylene (e-PTFE), polycarbonate (PC), polymethylmethacrylate (PMMA), polyethylene terephthalate (PET), or a combination thereof. In addition, the porous substrate film 102 may be a connected porous structure formed by stretching the plurality of fibers 103, so that the following solution may permeate thereto.

Thereafter, a step S12 is carried out, in which a piezoelectric material solution is permeated into the porous substrate film 102. For example, the piezoelectric material solution is coated on the porous substrate film 102, so that the piezoelectric material solution can be permeated into the porous substrate film 102. However, the invention is not limited thereto. The piezoelectric material solution is coated on the porous substrate film 102 by performing spin coating, blade coating, or screen printing, for example. In the embodiment, the spin coating is, for example, performed at 500 rpm to 1500 rpm for 5 to 15 seconds and the thickness of the coating is, for example, 2 μm to 4 μm. In other embodiments, the piezoelectric material solution may also be permeated into the porous substrate film 102 by immersing the porous substrate film 102 in the piezoelectric material solution. Additionally, a piezoelectric material 104 is, for example, a polymer material having dipoles and gained its piezoelectricity by polarizing the dipoles into orientation. In the embodiment, the polymer having a dipole is, for example, polyhexamethylene adipamide, poly(vinylidene fluoride) (PVDF), poly(vinylidenefluoride-trifluoroethylene) (P(VDF-TrFE)), polymide, or poly(L-lactic acid) (PLLA). In the embodiment, the piezoelectric material solution is formed by dissolving the piezoelectric material 104 in a solvent. However, the invention is not limited thereto. In other embodiments, the piezoelectric material solution is, for example, formed by other methods of dissolving or melting the piezoelectric material 104 into liquid form. Under the circumstances where the piezoelectric material solution is coated on the porous substrate film 102, the porous substrate film 102 is usually hydrophobic and the piezoelectric material 104 is usually hydrophilic, the solvent selected for forming the piezoelectric material solution must be capable of dissolving the piezoelectric material 104 and being permeated into the porous substrate film 102. So that the piezoelectric material 104 can be permeated into the porous substrate film 102 when coating the piezoelectric material solution on the porous substrate film 102. Therefore, the solvent for the piezoelectric material solution is selected based on the choice of the porous substrate film 102 and the piezoelectric material 104. In the embodiment, the solvent for the piezoelectric material solution is, for example, acetone or tetrahydrofuran. However, the invention is not limited thereto.

In another embodiment, before coating the piezoelectric material solution on the porous substrate film 102, a step of wetting the porous substrate film 102 by the enhancer solution is further included, wherein a polarity of the enhancer solution is lower than a polarity of the solvent for the piezoelectric material solution, as shown in step S11 in FIG. 1. In the embodiment, the enhancer solution is, for example, acetone or tetrahydrofuran, and the piezoelectric material solution is formed by dissolving the piezoelectric material 104 in the solvent. Such solvent is, for example, dimethyl formamide, dimethyl acetamide, or dimethyl sulfoxide, wherein a polarity index of acetone is 5.1, a polarity index of tetrahydrofuran is 4.0 (hereafter also referred to as low polarity solvent); and a polarity index of dimethyl formamide is 6.4, a polarity index of dimethyl acetamide is 6.5, and a polarity index of dimethyl sulfoxide is 7.2 (hereafter also referred to as high polarity solvent). Specifically, the porous substrate film 102 rejects the high polarity solvent due to its hydrophobic characteristic, and therefore the porous substrate film 102 is wetted by the low polarity solvent first so as to temporarily modify the hydrophobicity/hydrophilicity of the surface of the porous substrate film 102. As a result, the piezoelectric material 104 can be permeated into the porous substrate film 102 when coating the piezoelectric material solution formed by the high polarity solvent on the porous substrate film 102. However, the invention is not limited thereto.

In the embodiment, the concentration of the piezoelectric material 104 in the piezoelectric material solution is, for example, 20 percent by weight or less. In an embodiment, the concentration of the piezoelectric material solution is, for example, 15 percent by weight to 17 percent by weight. When the concentration of the piezoelectric material 104 in the piezoelectric material solution is higher than 20 percent by weight, the piezoelectric material solution becomes so viscous that the piezoelectric material solution may not be easily permeated into the porous substrate film 102, resulting in ununiform distribution. It is also worth mentioning that the amount of the piezoelectric material 104 covering on the fibers 103 depends on the conditions of the concentration of the piezoelectric material solution and, the condition of spin coating, and therefore may be adjusted according to actual needs of the experiments. For example, when the concentration of the piezoelectric material solution becomes too low (for example, lower than 10 percent by weight), if the amount of the piezoelectric material 104 covering on the fibers 103 is not sufficient after one spin coating is performed, then the spin coating is performed again until the piezoelectric membrane is covered with the desired amount of the piezoelectric material 104.

Next, a step S14 is carried out, in which the piezoelectric material solution is hardened such that the fibers 103 are partially covered with the piezoelectric material 104. In the embodiment, the method of hardening the piezoelectric material solution includes performing a heating process to volatilize and dry the solvent in the piezoelectric material solution, so that the fibers 103 can be partially covered with the piezoelectric material 104. However, the invention is not limited thereto.

Thereafter, a step S16 may be selectively carried out to polarize a piezoelectric membrane 100, so that the piezoelectric material 104 can obtain the piezoelectric effect; however, the invention is not limited thereto. The piezoelectric membrane 100 is polarized by performing corona polarization, thermal polarization, low energy electron beam polarization, electrospun, radiation polarization, or so on, for example. In an embodiment, the thermal polarization is performed to polarize the piezoelectric membrane 100, and a polarization electric field in performing the thermal polarization is, for example, 200 MV/m to 800 MV/m; a heating temperature is, for example, 90° C. to 125° C. and a polarization time is, for example, 30 to 60 minutes.

Then, referring to both FIGS. 1 and 3, after the step S16 is performed, a step S18 may be selectively carried out, in which a polymer solution is applied on the two main surfaces of the porous substrate film 102 and then hardened so as to form a polymer layer 106. In the embodiment, the polymer solution is formed by dissolving a polymer material in a solvent; however, the invention is not limited thereto. The polymer material in the polymer solution is, for example, a space-charge electret material which has good capability in storing space charges. In the embodiment, the space-charge electret material is, for example, polypropylene, polystyrene (PS), polycarbonate, polyvinyl chloride (PVC), polymethylmethacrylate (PMMA), polyethylene terephthalate (PET), poly-tetrafluoroethylene (PTFE), fluorinated ethylene propylene (FEP), or cyclic olefin copolymer (COC). The solvent for the polymer solution is, for example, toluene. The polymer solution is coated by performing spin coating, blade coating, or screen printing, for example. In an embodiment, the spin coating is, for example, performed at 500 rpm to 1500 rpm for 5 to 15 seconds and the thickness of the coating is, for example, 1 μm to 2 μm. A method of hardening the polymer solution includes performing a heating process so that the solvent for the polymer solution is volatilized and dried; however the invention is not limited thereto.

Thereafter, a step S20 may be selectively carried out to polarize the piezoelectric membrane 100, such that space dipoles are formed in the porous substrate film of the piezoelectric membrane 100 and thus the piezoelectric membrane 100 can obtain the piezoelectric effect; however, the invention is not limited thereto. The method of polarizing the piezoelectric membrane 100 includes performing corona polarization, thermal polarization, low energy electron beam polarization, electrospun, radiation polarization, or so on. In an embodiment, the thermal polarization is performed to polarize the piezoelectric membrane 100; a polarization electric field in performing the thermal polarization is, for example, 3 MV/m to 5 MV/m, and a polarization time is, for example, 3 to 30 seconds.

Accordingly, in the method of forming the piezoelectric membrane of the invention, the porous piezoelectric membrane 100 is formed by permeating the piezoelectric material solution into the porous substrate film 102 and then hardening the piezoelectric material solution to cover the fibers 103 in the porous substrate film with the piezoelectric material 104. Therefore, the forming process is rather easy and straight forward, by which a porous piezoelectric membrane with a large area may be effectively formed.

Next, please refer to FIG. 2 again. The piezoelectric membrane 100 formed by the method of forming the piezoelectric membrane of the invention includes the porous substrate film 102, which is a membrane structure having two main surfaces and formed by the plurality of fibers 103, and the piezoelectric material 104 covering a portion of the fibers 103.

The material of the porous substrate film 102 is, for example, porous electret material. In the embodiment, the material of the porous electret material is, for example, polypropylene (PP), polytetrafluoroethylene (PTFE), expanded polytetrafluoroethylene (e-PTFE), polycarbonate (PC), polymethylmethacrylate (PMMA), or polyethylene terephthalate (PET).

The piezoelectric material 104 is, for example, a polymer material having dipoles. In the embodiment, the polymer material having dipoles is, for example, polyhexamethylene adipamide, poly(vinylidene fluoride) (PVDF), poly(vinylidenefluoride-trifluoroethylene) (P(VDF-TrFE)), polymide, or poly(L-lactic acid) (PLLA).

It needs to be specifically pointed out that the piezoelectric membrane 100 formed by using the porous substrate film 102 and the piezoelectric material 104 which permeates into the porous substrate film 102 and covers on the fibers 103 thereof may also be regarded as a piezoelectric membrane having a porous structure.

In addition, please refer to FIG. 3 again. The piezoelectric membrane 100 may further include the polymer layer 106 disposed on the two main surfaces of the porous substrate film 102 so as to form a sandwiched structure. The polymer layer 106 is, for example, a space-charge electret layer. In the embodiment, the material of the space-charge electret layer is, for example, polypropylene, polystyrene (PS), polycarbonate, polyvinyl chloride (PVC), polymethylmethacrylate (PMMA), polyethylene terephthalate (PET), poly-tetrafluoroethylene (PTFE), fluorinated ethylene propylene (FEP), or cyclic olefin copolymer (COC).

Furthermore, in an embodiment, the porosity of the piezoelectric membrane 100 may be 10% to 95% through adjusting parameters such as the percentage of the concentration of the piezoelectric material 104 in the piezoelectric material solution, the number of times of coating or immersing, time of coating or immersing and so on. In another embodiment, the porosity of the piezoelectric membrane 100 is, for example, 60% to 80%.

Besides, in terms of utility, the thickness of the piezoelectric membrane 100 with the polymer layer 106 disposed thereon is, for example, 1 μm to 1 mm. In an embodiment, the thickness of the piezoelectric membrane 100 with the polymer layer 106 disposed thereon is, for example, 13 μm to 15 μm.

It needs to be specifically pointed out that, according to an embodiment of the invention, the polymer layer 106 may effectively prevent the space charges in the piezoelectric membrane 100 from losing, and thus the space charges may be stored between interfaces. Therefore, the space charges stored within the porous structure of the piezoelectric membrane 100 form the space dipoles in the piezoelectric membrane 100, so that enhance the piezoelectricity of the piezoelectric membrane 100. Therefore, the piezoelectric membrane 100 provided in an embodiment of the invention may combine the piezoelectric effect generated by the space dipoles within the piezoelectric membrane 100 and piezoelectric effect generated by dipoles of the piezoelectric material 104, such that the piezoelectric effect of the porous piezoelectric membrane 100 is effectively increased.

Additionally, since the piezoelectric membrane 100 with a porous structure of the invention has a good piezoelectric effect, the piezoelectric membrane 100 may have applications such as membrane type pressure sensors and ultrasonic transducers.

The following experiment examples are used for providing a detailed description of the piezoelectric membrane and the forming method thereof in the aforementioned embodiments. However, the data result in the following experiment examples are used only for describing the piezoelectric characteristic of the piezoelectric membrane formed according to the aforementioned embodiments instead of for limiting the scope of the invention.

### EXPERIMENT EXAMPLE 1

First of all, an expanded polytetrafluoroethylene (ePTFE) membrane (5 cm in length and width) (the aforementioned porous substrate film) of a thickness of 25 nm is lied down on a glass carrier. Then, the glass carrier is placed on a stage of a spin coating machine; the acetone (99.9%, 3 ml to 5 ml) (the aforementioned enhancer solution) is dropped in the ePTFE membrane to wet the whole membrane. Thereafter, 15 percent by weight of poly(vinylidenefluoride-trifluoroethylene) (P(VDF-TrFE)) solution (the aforementioned piezoelectric material solution, 3 ml to 5 ml) prepared by using dimethyl sulfoxide as a solvent is immediately dropped into the wetted ePTFE membrane, and two stages of spin coating are performed so that the P(VDF-TrFE) solution may be uniformly distributed on the ePTFE membrane. The first stage of spin coating is carried out at 500 rpm for 5 seconds; the second stage of spin coating is carried out at 1500 rpm for 15 seconds. After the spin coating is completed, a testing piece is placed on a thermal plate and baked to dry at 70° C. for 1 hour so as to form a porous P(VDF-TrFE)/ePTFE composite piezoelectric membrane (hereafter piezoelectric membrane 1). As compared to the ePTFE membrane without the P(VDF-TrFE) coating, the piezoelectric membrane 1 is more transparent, indicating that there is sufficient P(VDF-TrFE) covering on the fibers of the ePTFE membrane.

Next, the piezoelectric membrane 1 is taken off and placed in an oven to be treated by a thermal treatment. In the oven, the temperature is increased to 135° C. and maintained for 3 hours; then the temperature is decreased to 65° C. and maintained for 2 hours so that the P(VDF-TrFE) of the piezoelectric membrane 1 is converted into a β-phase crystal state with the best piezoelectric characteristic. Then, the aforementioned thermal treatment is repeated one more time after the temperature is dropped to the room temperature so that the piezoelectric membrane 1 gained the piezoelectric effect.

### EXPERIMENT EXAMPLE 2

A piezoelectric membrane 2 is prepared by using a method similar to the one in the experiment example 1, except that after performing the thermal polarization to the piezoelectric membrane 1, a cyclic olefin copolymer solution (the aforementioned polymer solution) is coated on the two main surfaces of the piezoelectric membrane 1.

The piezoelectric membrane 1 being thermal polarized is placed on the stage of the spin coating machine; two stages of spin coating are performed so that 5% of the cyclic olefin copolymer solution (3 ml to 5 ml) may be uniformly distributed on the two main surface of the piezoelectric membrane 1 to form the piezoelectric membrane 2 with the cyclic olefin copolymer covering on the outside thereof. By covering a protection layer of the piezoelectric membrane with the cyclic olefin copolymer, the space charges are better retained and form the space dipoles. Then, a general polarization may also be performed to the piezoelectric membrane 2 to exert the piezoelectric effect.

### Polarization

Polarization treatment needs to be performed on the piezoelectric membrane 1 and the piezoelectric membrane 2 for these piezoelectric membranes gaining piezoelectricity.

The instrument and experiment method for polarization adopted are as follows:

Instrument: needle corona discharge system (direct current high voltage source: FX20N6 high voltage DC power supply, Glassman High Voltage Incorporated, America).

Experiment method: In order for more ions to be accumulated on the surface of the piezoelectric membrane, a distance between needle electrode and plate electrode is shortened to the shortest distance of 3 cm for corona stabilization , so that the corona is more focused. A voltage of +20 KV is applied on the needle.

In summary, the method of forming the piezoelectric membrane provided in the aforementioned embodiments includes steps of permeating the piezoelectric material solution into the porous substrate film and then hardening the piezoelectric material solution to cover the fibers with the piezoelectric material. The method of forming the piezoelectric membrane provided by this invention is capable of forming the large-areaed piezoelectric membrane and the piezoelectric membrane with porosity ranging from 10% to 95%. In addition, the piezoelectric membrane provided in the embodiments is the composite piezoelectric membrane have porous substrate film made of the porous electret material and the piezoelectric material. Furthermore, the polymer layer coated on the cover effectively improves the space charge storage capability of the piezoelectric membrane, so that the piezoelectric membrane has both the dipole charges of the piezoelectric material and the space dipoles to contribute to the piezoelectric effect thereof.

Although the invention has been disclosed by the above embodiments, the embodiments are not intended to limit the invention. It will be apparent to those skilled in the art that various modifications and variations can be made to the structure of the invention without departing from the scope or spirit of the invention. Therefore, the protecting range of the invention falls in the appended claims.

1. A method of forming a piezoelectric membrane, comprising:
providing a porous substrate film, which is a membrane structure with two main surfaces and formed by a plurality of fibers;
permeating a piezoelectric material solution into the porous substrate film; and
hardening the piezoelectric material solution so that the fibers are covered by a piezoelectric material, wherein the piezoelectric material comprises polyhexamethylene adipamide, poly(vinylidene fluoride) (PVDF), poly(vinylidenefluoride-trifluoroethylene) (P(VDF-TrFE)), or poly(L-lactic acid) (PLLA).

2. The method of forming the piezoelectric membrane according to claim 1, wherein a method of permeating the piezoelectric material solution into the porous substrate film comprises coating the piezoelectric material solution on the porous substrate film.

3. The method of forming the piezoelectric membrane according to claim 2, wherein a method of coating the piezoelectric material solution on the porous substrate film comprises spin coating, blade coating, or screen printing.

4. The method of forming the piezoelectric membrane according to claim 2, wherein the piezoelectric material solution is formed by dissolving the piezoelectric material in a solvent, and the solvent comprises acetone or tetrahydrofuran.

5. The method of forming the piezoelectric membrane according to claim 4, wherein a concentration of the piezoelectric material in the piezoelectric material solution is 20 percent by weight or less.

6. The method of forming the piezoelectric membrane according to claim 2, before coating the piezoelectric material solution on the porous substrate film, further comprising wetting the porous substrate film by a enhancer solution, wherein a polarity index of the enhancer solution is lower than a polarity index of a solvent for the piezoelectric material solution.

7. The method of forming the piezoelectric membrane according to claim 6, wherein the piezoelectric material solution is formed by dissolving the piezoelectric material in a solvent, the solvent comprises dimethyl formamide, dimethyl acetamide, or dimethyl sulfoxide, and the enhancer solution comprises acetone or tetrahydrofuran.

8. The method of forming the piezoelectric membrane according to claim 7, wherein a concentration of the piezoelectric material in the piezoelectric material solution is 20 percent by weight or less.

9. The method of forming the piezoelectric membrane according to claim 1, wherein a method of permeating the piezoelectric material solution into the porous substrate film comprises immersing the porous substrate film in the piezoelectric material solution.

10. The method of forming the piezoelectric membrane according to claim 1, wherein a material of the porous substrate film comprises porous electret material.

11. The method of forming the piezoelectric membrane according to claim 10, wherein the porous electret material comprises polypropylene (PP), polytetrafluoroethylene (PTFE), expanded polytetrafluoroethylene (e-PTFE), polycarbonate (PC), polymethylmethacrylate (PMMA), or polyethylene terephthalate (PET).

12. (canceled)

13. The method of forming the piezoelectric membrane according to claim 1, after hardening the piezoelectric material solution, further comprising coating a polymer solution on the two main surfaces of the porous substrate film and then hardening the polymer solution.

14. The method of forming the piezoelectric membrane according to claim 13, before coating the polymer solution on the two main surfaces of the porous substrate film and then hardening the polymer solution, further comprising polarizing the piezoelectric membrane.

15. The method of forming the piezoelectric membrane according to claim 13, after coating the polymer solution on the two main surfaces of the porous substrate film and then hardening the polymer solution, further comprising polarizing the piezoelectric membrane.

16. The method of forming the piezoelectric membrane according to claim 13, wherein the polymer solution is formed by dissolving a polymer material in a solvent, the polymer material comprises polypropylene, polystyrene (PS), polycarbonate, polyvinyl chloride (PVC), polymethylmethacrylate (PMMA), polyethylene terephthalate (PET), poly-tetrafluoroethylene (PTFE), fluorinated ethylene propylene (FEP), or cyclic olefin copolymer (COC).

17. A piezoelectric membrane, comprising:
a porous substrate film, the porous substrate film is a membrane structure having two main surfaces and is formed by a plurality of fibers; and
a piezoelectric material, coating a portion of the fibers.

18. The piezoelectric membrane according to claim 17, wherein a material of the porous substrate film comprises a porous electret material.

19. The piezoelectric membrane according to claim 18, wherein the porous electret material comprises polypropylene (PP), polytetrafluoroethylene (PTFE), expanded polytetrafluoroethylene (e-PTFE), polycarbonate (PC), polymethylmethacrylate (PMMA), or polyethylene terephthalate (PET).

20. The piezoelectric membrane according to claim 17, wherein the piezoelectric material comprises polyhexamethylene adipamide, poly(vinylidene fluoride) (PVDF), poly(vinylidenefluoride-trifluoroethylene) (P(VDF-TrFE)), polymide, or poly(L-lactic acid) (PLLA).

21. The piezoelectric membrane according to claim 17, wherein a porosity of the piezoelectric membrane is 10% to 95%.

22. The piezoelectric membrane according to claim 17, wherein a porosity of the piezoelectric membrane is 60% to 80%.

23. The piezoelectric membrane according to claim 17, further comprising a polymer layer, disposed on the two main surfaces of the porous substrate film.

24. The piezoelectric membrane according to claim 23, wherein a material of the polymer layer comprises polypropylene, polystyrene (PS), polycarbonate, polyvinyl chloride (PVC), polymethylmethacrylate (PMMA), polyethylene terephthalate (PET), poly-tetrafluoroethylene (PTFE), fluorinated ethylene propylene (FEP), or cyclic olefin copolymer (COC).

25. The piezoelectric membrane according to claim 23, wherein a thickness of the piezoelectric membrane is 1 μm to 1 mm.
